(19) United States
(12) Patent Application Publication
(10) Pub. No.: US 2015/0332926 A1
(43) Pub. Date: Nov. 19, 2015

(54) Method of Forming High-K Gates Dielectrics

(71) Applicant: UNITED MICROELECTRONICS CORP., Hsin-Chu City (TW)

(72) Inventors: Jian-Cun Ke, Tainan City (TW); Chih-Wei Yang, Kaohsiung City (TW); Chia-Fu Hsu, Tainan City (TW)

(73) Assignee: UNITED MICROELECTRONICS CORP., Hsin-Chu City (TW)

(21) Appl. No.: 14/280,654

(22) Filed: May 18, 2014

(51) Int. Cl. H01L 21/28; H01L 29/66

(52) U.S. Cl. CPC H01L 21/28229; H01L 29/66568

(57) ABSTRACT

A method for fabricating semiconductor device is disclosed. The method includes the steps of: providing a substrate; injecting a first precursor and forming an interfacial layer on the substrate; and injecting a second precursor and performing a thermal treatment for forming an interface layer on the interfacial layer.

### BACKGROUND OF THE INVENTION

1. Field of the Invention

The invention relates to a method for fabricating semiconductor device, and more particularly, to a method for producing semiconductor device characterized by reduction of negative bias temperature instability (NBTI) by injecting two precursors during the formation of a silicon dioxide interfacial layer.

2. Description of the Prior Art

With the continuous development of semiconductor technologies, feature size of metal-oxide-semiconductor (MOS) transistors has been reduced. Accordingly, the thickness of gate dielectric layers in the MOS transistors has become thinner and thinner. When a gate dielectric layer is overly thinned, however, various issues may occur. These issues may include time-related voltage breakdowns, hot carrier effects, and diffusion of impurities from the gate electrode toward the substrate. This can adversely affect stability and reliability of the formed transistors. Currently, use of SiO₂ as a gate dielectric material may reach its physical limitation. Replacing SiO₂ gate dielectric layer with high-k gate dielectric layer may significantly increase the physical thickness with the same effective oxide thickness (EOT) achieved to reduce leakage current of the gate electrode.

Most of high-k gate dielectric layers are made of metal oxides, which do not have fixed atomic coordinates. Compared with SiO₂ gate dielectric material, high-k gate dielectric materials have much poorer bonding stability with the silicon substrate. Consequently, interfacial defects are formed between the high-k gate dielectric layer and the silicon substrate. The interfacial defects may be combined with oxygen to produce interstitial oxygen atoms and positively charged oxygen vacancies, which may further be combined with hydrogen to form unstable hydrogen bonds. Such unstable hydrogen bonds can cause a PMOS transistor to have negative bias temperature instability (NBTI). That is, at high temperatures and when the gate electrode is negatively biased, electrical parameter drift of the PMOS transistor may occur. Accordingly, there is a need to provide transistors with reduced NBTI and methods for fabricating such transistors.

### SUMMARY OF THE INVENTION

It is therefore an objective of the present invention to provide a method for fabricating semiconductor device for resolving aforementioned issues.

According to a preferred embodiment of the present invention, a method for fabricating semiconductor device includes the steps of: providing a substrate; injecting a first precursor and forming an interfacial layer on the substrate; and injecting a second precursor and performing a thermal treatment for forming an interface layer on the interfacial layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating semiconductor device according to a preferred embodiment of the present invention.

### DETAILED DESCRIPTION

Referring to FIGS. 1-4, FIGS. 1-4 illustrate a method for fabricating semiconductor device according to a preferred embodiment of the present invention. As shown in FIG. 1, a substrate 12, such as a wafer or a silicon-on-insulator (SOI) substrate is provided. Next, a first precursor is injected to form an interfacial layer 14 on the substrate 12. According to a preferred embodiment of the present invention, the interfacial layer 14 is preferably grown by performing an in-situ steam generation (ISSG) process along with the injection of the first precursor, in which the first precursor preferably includes N₂O and H₂. By injection the first precursor at a temperature between 800° C. to 1100° C., and more preferably at 900° C., and at a duration between 6 to 24 seconds, and more preferably at around 12 seconds, an interfacial layer 14 composed of silicon dioxide with a thickness of approximately 9 Angstroms is formed on the surface of the substrate 12.

After the formation of the interfacial layer 14, a second precursor is injected and a thermal treatment is performed to form an interface layer 16 on the interfacial layer 14. According to a preferred embodiment of the present invention, the second precursor preferably composed of N₂ and O₂ is injected while the thermal treatment is conducted to form the interface layer 16, in which the thermal treatment, preferably being a rapid thermal anneal process, is conducted at a temperature between 800° C. to 1100° C., and more preferably at 1040° C., and at a duration between 6 to 24 seconds, and more preferably at around 8.2 seconds. The interface layer 16 formed atop the interfacial layer 14 is approximately 1/10 of the Total thickness of both the interfacial layer 14 and the interface layer 16 combined, in which the total thickness of the interfacial layer 14 and the interface layer 16 is approximately 10.5 Angstroms.

Preferably, the interface layer 16 is composed of silicon dioxide, and the step of injecting the first precursor for forming the interfacial layer 14 and the step of injecting the second precursor for forming the interface layer 16 are carried out in the same chamber.

It is to be noted that in conventional process for fabricating MOS transistors, voids are often trapped within the interfacial layer, which not only weakens the interface between interfacial layer and the high-k dielectric layer thereon, but also worsens the NBTI issue substantially. By utilizing a first precursor composed of N₂O and H₂ to form an interfacial layer 14 on the substrate and then utilizing a second precursor composed of N₂ and O₂ to form an interface layer 16 atop the interfacial layer 14, the present invention is able to eliminate voids trapped inside the interfacial layer while repairing the surface profile between the interface layer 16 and the high-k dielectric layer formed thereafter so that when the two layers 14 and 16 are formed on the substrate 12, issues such as NBTI instability could be minimized and performance of the device could be improved substantially.

Next, a high-k dielectric layer 18, a bottom barrier metal (BBM) layer 20, a material layer 22, and an optional hard mask (not shown) are sequentially formed on the interface layer 16. For the sake of brevity, the optional hard mask is not included in the following embodiment.

Preferably, the high-k dielectric layer 18 could be made of dielectric materials having a dielectric constant (k value) larger than 4, and the material of the high-k dielectric layer 18 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

The BBM layer 20 is preferably selected from the group consisting of tantalum (Ta), titanium (Ti), titanium nitride (TiN), tantalum nitride (TaN), and tungsten nitride (WN), and more preferably TiN, the material layer 22 preferably serving as a gate electrode is composed of single crystal silicon, amorphous silicon, or doped polysilicon, and the optical hard mask is selected from the group consisting of SiC, SiON, SiN, SiCN, and SiBN.

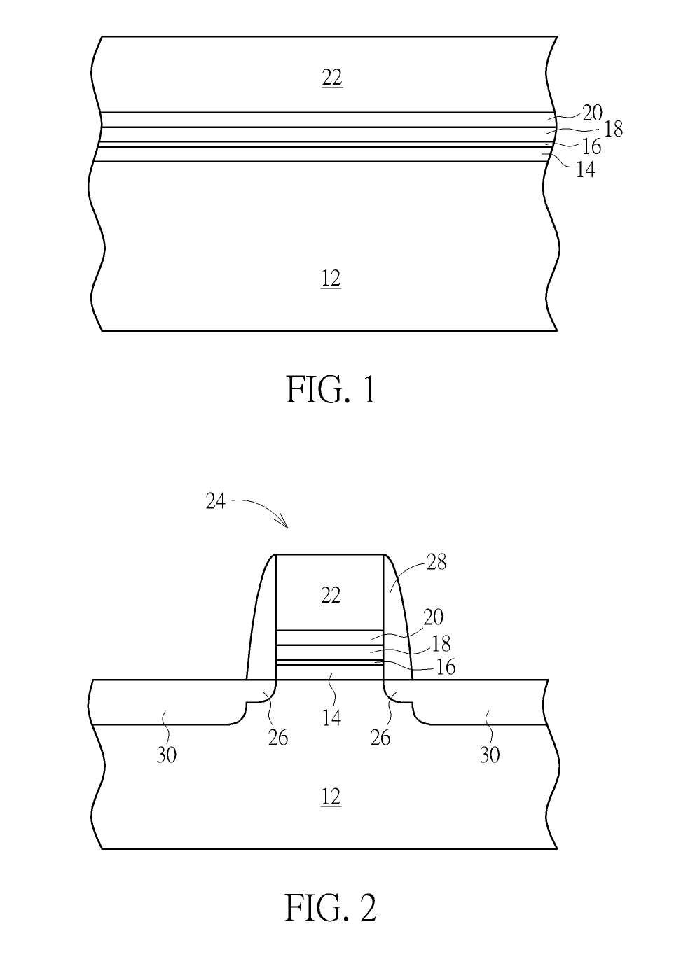

Next, as shown in FIG. 2, a pattern transfer is performed by first forming a patterned resist (not shown) on the material layer 22 and then conducting one or multiple etching process to remove part of the material layer 22, BBM layer 20, high-k dielectric layer 18, interface layer 16, and interfacial layer 14 not covered by the patterned resist for forming a gate structure 24. In other words, the gate structure 24 preferably includes a patterned interfacial layer 14, patterned interface layer 16, patterned high-k dielectric layer 18, patterned BBM layer 20, and patterned material layer 22.

After forming the gate structure 24, a selective liner (not shown) could be formed on the sidewall of the gate structure 24, and an ion implantation is conducted to form a lightly doped drain 26 in the substrate 12 adjacent to two sides of the gate structure 24. Next, a spacer 28 could be formed on the sidewall of the gate structure 24, and another ion implantation is conducted to form a source/drain region 30 in the substrate 12 adjacent to two sides of the spacer 28. Depending on the demand of the product, the fabrication of a MOS transistor could be completed at this stage according to an embodiment of the present invention.

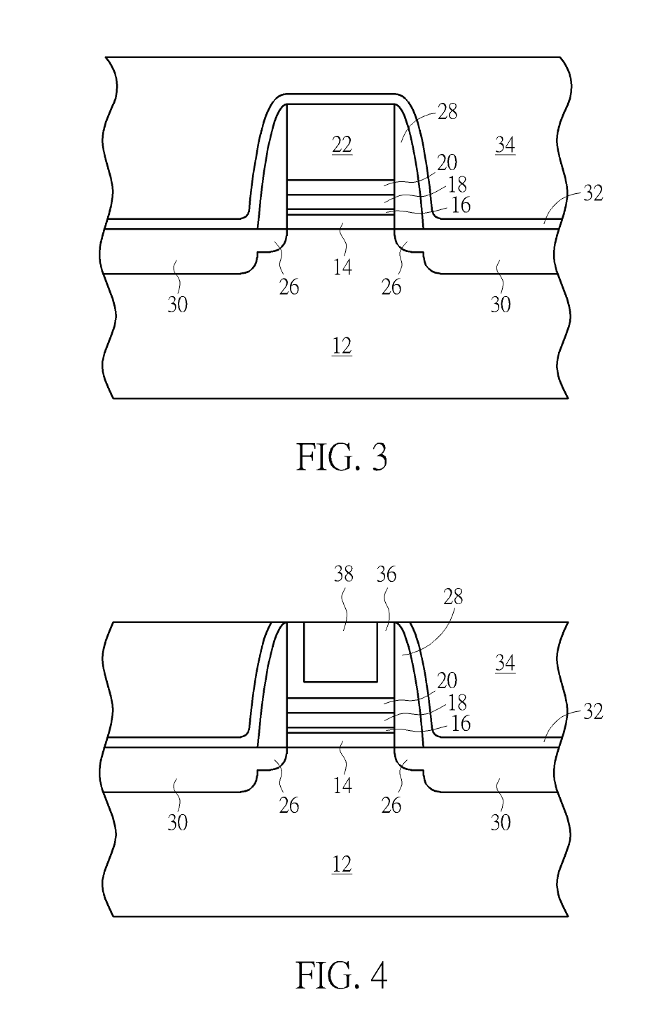

If a metal gate transistor were to be fabricated, according to another embodiment of the present invention, as shown in FIG. 3, a contact etch stop layer (CESL) 32 could be formed on the substrate 12 to cover the gate structure 24, and an interlayer dielectric (ILD) layer 34 is deposited on the CESL 32 thereafter. It should be noted that elements such as raised epitaxial layers and salicides could also be formed before the formation of the CESL 32, and as the process for fabricating these elements are well known to those skilled in the art, the details of which are not described herein for sake of brevity.

Next, as shown in FIG. 4, a planarizing process, such as a chemical mechanical polishing (CMP) process is performed to partially remove the ILD layer 34 and the CESL 32 so that the top of the gate electrode 22 composed of polysilicon within the gate structure 24 is exposed and substantially even with the surface of the ILD layer 34.

Next, a replacement metal gate (RMG) process is conducted to form a metal gate. According to a preferred embodiment of the present invention, the RMG process could be carried out by first performing a selective dry etching or wet etching process, such as using etchants including ammonium hydroxide (NH₄OH) or tetramethylammonium hydroxide (TMAH) to remove the amorphous silicon or polysilicon material from the gate electrode 22 of the gate structure 24 without etching the ILD layer 34 for forming a recess (not shown).

A work function layer 36 and a low resistance metal layer 38 are then deposited to fill the recess, and a planarizing process, such as a CMP process is carried out to planarize the low resistance metal layer 38 and the work function layer 36 for forming a metal gate.

Depending on the nature of the device being fabricated, the work function layer 36 may be a n-type work function layer or a p-type work function layer. Preferably, the n-type work function layer has a work function ranging between 3.9 eV and 4.3 eV and may be selected from a group consisting of titanium aluminide (TiAl), zirconium aluminide (ZrAl), tungsten aluminide (WAl), tantalum aluminide (TaAl), and hafnium aluminide (HfAl), but not limited thereto. The p-type work function layer has a work function ranging between 4.8 eV and 5.2 eV and may be selected from a group consisting of titanium nitride (TiN), tantalum nitride (TaN), and tantalum carbide (TaC), but not limited thereto.

Preferably, the low resistance metal layer 38 is selected from a group consisting of Al, Ti, Ta, W, Nb, Mo, Cu, TiN, TiC, TaN, Ti/W, TiAl, CoWP, and composite metal such as Ti/TiN, but not limited thereto. This completes the fabrication of a metal gate transistor.

In addition to the high-k first process disclosed in the aforementioned embodiment, the aforementioned approach of injecting two different precursors for forming an interfacial layer and an interface could also be applied to a high-k last process. For instance, instead of utilizing two different precursors to grow an interfacial layer and an interface layer on the substrate in the beginning, a single interfacial layer could be first grown through an ISSG process on a substrate, and a material layer, such as a polysilicon layer is deposited on the interfacial layer thereon. After patterning the polysilicon layer and interfacial layer into a gate structure, elements such as spacer, lightly doped drain, source/drain region, CESL, and ILD layer are formed according to the steps shown in FIGS. 2-3. After conducting a planarizing process to expose the polysilicon layer within the gate structure and then removing the polysilicon layer and the interfacial layer within the gate structure to form a recess, a first precursor is injected to form another interfacial layer in the recess and a second precursor is injected thereafter along with a thermal treatment to form an interface layer atop the interfacial layer. The fabrication parameters and steps for forming these two interfacial layer and interface layer could be similar to the ones disclosed in the aforementioned embodiment, and the details of which are not explained herein for sake of brevity. After forming the interfacial layer and the interface layer, a high-k dielectric layer, work function layer, and low resistance metal layer are deposited into the recess to complete the fabrication of a metal gate transistor.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate;
injecting a first precursor and forming an interfacial layer on the substrate; and
injecting a second precursor and performing a thermal treatment for forming an interface layer on the interfacial layer after forming the interfacial layer on the substrate, wherein the thickness of the interface layer is 1/10 of the total thickness of the interfacial layer and the interface layer.

2. The method of claim 1, further comprising:
forming a high-k dielectric layer on the interface layer;
forming a bottom barrier metal (BBM) layer on the high-k dielectric layer;
forming a material layer on the BBM layer;
patterning the material layer, the BBM layer, and the high-k dielectric layer for forming a gate structure; and
forming a source/drain region in the substrate adjacent to two sides of the gate structure.

3. The method of claim 2, wherein the BBM layer comprises TiN.

4. The method of claim 2, wherein the material layer comprises amorphous silicon or polysilicon.

5. The method of claim 1, wherein the interfacial layer comprises silicon dioxide.

6. The method of claim 1, wherein the interface layer comprises silicon dioxide.

7. The method of claim 1, wherein the first precursor comprises N₂O and H₂.

8. The method of claim 1, wherein the second precursor comprises N₂ and O₂.

9. The method of claim 1, further comprising performing an in-situ stream generation (ISSG) process for forming the interfacial layer.

10. The method of claim 1, wherein the thermal treatment comprises a rapid thermal anneal process.

11. The method of claim 1, wherein the temperature of the thermal treatment is between 800° C. to 1100° C.

12. The method of claim 1, wherein the duration of the thermal treatment is between 6 to 24 seconds.
